(19) United States
(12) Patent Application Publication
(10) Pub. No.: US 2019/0355595 A1
(43) Pub. Date: Nov. 21, 2019

(54) System and Method for Improved Chemical Etching

(71) Applicant: Yangtze Memory Technologies Co., Ltd, Wuhan (CN)

(72) Inventors: Wenbin SUN, Wuhan (CN); Yangbo JIANG, Wuhan (CN); Ya Jun WANG, Wuhan (CN); Li Xun Gu, Wuhan (CN); Rong XU, Wuhan (CN); Liang Hui WU, Wuhan (CN)

(73) Assignee: Yangtze Memory Technologies Co., Ltd, Wuhan (CN)

(21) Appl. No.: 16/046,039

(22) Filed: Jul. 26, 2018

Related U.S. Application Data
(63) Continuation of application No. PCT/CN2018/087290, filed on May 17, 2018.

(51) Int. Cl. H01L 21/67; H01L 21/306; H01L 21/311

(52) U.S. Cl. CPC H01L 21/67086; H01L 21/31111; H01L 21/30604

(57) ABSTRACT

A chemical etching apparatus and methods of using are disclosed. An apparatus used for chemical etching includes a bath designed to hold a first liquid. A liquid supply pipe runs along a bottom portion of the bath. The liquid supply pipe has a first plurality of openings along a length of the liquid supply pipe along the bottom portion of the bath. A gas supply pipe runs along the bottom portion of the bath. The gas supply pipe has a second plurality of openings along a length of the gas supply pipe along the bottom portion of the bath. The liquid supply pipe introduces a second liquid into the first liquid via the first plurality of openings and the gas supply pipe introduces a gas into the first liquid via the second plurality of openings.

### CROSS REFERENCE TO RELATED APPLICATIONS

This application is a continuation of PCT Application No. PCT/CN2018/087290, filed on May 17, 2018, the disclosure of which is incorporated by reference herein in its entirety.

### BACKGROUND

Embodiments of the present disclosure relate to a chemical etching apparatus used in semiconductor fabrication.

Chemical etching of semiconductor wafers using wet etchants is commonly performed in the industry to remove various materials, or to etch the semiconductor wafer itself. The wafers to be subjected to the chemical etch are placed in a solution bath containing a particular chemical etchant for a period of time that determines how much material is etched away. The solution bath is often sized to facilitate batch processing of numerous wafers at the same time. It can be challenging to ensure that each wafer of a given batch is adequately etched, or that the etch rates across all wafers placed within the solution bath is equal.

### BRIEF SUMMARY

Embodiments of an apparatus used for chemical etching of substrates and methods of its use are disclosed herein. The disclosed apparatus and method provide numerous benefits, including, but not limited to more uniform etch rates across all wafers and increased product yield from each batch of processed wafers.

In some embodiments, an apparatus used for chemical etching includes a bath designed to hold a first liquid. A liquid supply pipe runs along a bottom portion of the bath. The liquid supply pipe has a first plurality of openings along a length of the liquid supply pipe along the bottom portion of the bath. A gas supply pipe runs along the bottom portion of the bath. The gas supply pipe has a second plurality of openings along a length of the gas supply pipe along the bottom portion of the bath. The liquid supply pipe introduces a second liquid into the first liquid via the first plurality of openings and the gas supply pipe introduces a gas into the first liquid via the second plurality of openings.

In some embodiments, the bath is designed to support a structure that holds one or more substrates.

In some embodiments, the gas includes nitrogen.

In some embodiments, each of the first plurality of openings and second plurality of openings has a diameter between 0.10 mm and 0.20 mm.

In some embodiments, the liquid supply pipe and the gas supply pipe run parallel to each other along the bottom portion of the bath.

In some embodiments, each of the first plurality of openings is aligned with a corresponding opening of the second plurality of openings in a direction perpendicular to the length of each of the gas supply pipe and the liquid supply pipe.

In some embodiments, the apparatus also includes a plurality of liquid supply pipes, each running along the bottom portion of the bath and parallel to each other.

In some embodiments, the apparatus also includes a plurality of gas supply pipes each running along the bottom portion of the bath and parallel to each other.

In some embodiments, the plurality of gas supply pipes combine into a single inlet gas pipe outside of the bath.

In some embodiments, the apparatus also includes a valve on each of the plurality of gas supply pipes, and configured to independently control a flow rate of gas within each of the plurality of gas supply pipes.

In some embodiments, a chemical etching method includes loading a first liquid into a bath. The method also includes flowing a second liquid through a liquid supply pipe running along a bottom portion of the bath, and introducing the second liquid into the first liquid via a first plurality of openings along a length of the liquid supply pipe that runs along the bottom portion of the bath. The method includes flowing a gas through a gas supply pipe running along the bottom portion of the bath, and introducing the gas into the first liquid via a second plurality of openings along a length of the gas supply pipe that runs along the bottom portion of the bath.

In some embodiments, the method includes loading one or more substrates into a structure, and submerging the structure into the bath holding the first liquid.

In some embodiments, flowing the second liquid and flowing the gas occurs simultaneously.

In some embodiments, flowing the second liquid includes flowing the second liquid through a plurality of liquid supply pipes along the bottom portion of the bath.

In some embodiments, flowing the gas includes flowing the gas through a plurality of gas supply pipes along the bottom portion of the bath.

In some embodiments, the method also includes adjusting a flow rate of the gas within each of the plurality of gas supply pipes using valves coupled to each of the plurality of gas supply pipes.

In some embodiments, the method also includes agitating the first liquid and the second liquid around one or more substrates using the gas introduced into the first liquid via the second plurality of openings.

In some embodiments, forming the one or more first holes further includes forming the one or more first holes through at least a portion of the insulating material in the first one or more recesses.

In some embodiments, the gas comprises nitrogen.

In some embodiments, introducing the second liquid into the first liquid and introducing the gas into the first liquid occurs simultaneously.

In some embodiments, the method also includes etching a material on one or more substrates using at least the second liquid.

### BRIEF DESCRIPTION OF THE DRAWINGS

Aspects of the present disclosure are best understood from the following detailed description when reading with the accompanying figures. It is noted that, in accordance with the common practice in the industry, various features are not drawn to scale. In fact, the dimensions of the various features may be arbitrarily increased or reduced for clarity of illustration and discussion.

FIG. 1 is a first view of an improved chemical etching bath, according to some embodiments.

FIG. 2 is a second view of the improved chemical etching bath, according to some embodiments.

FIG. 3 is a third view of the improved chemical etching bath, according to some embodiments.

FIG. 4 is an illustration of an etching process using the improved chemical etching bath, according to some embodiments.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” or “wafer” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

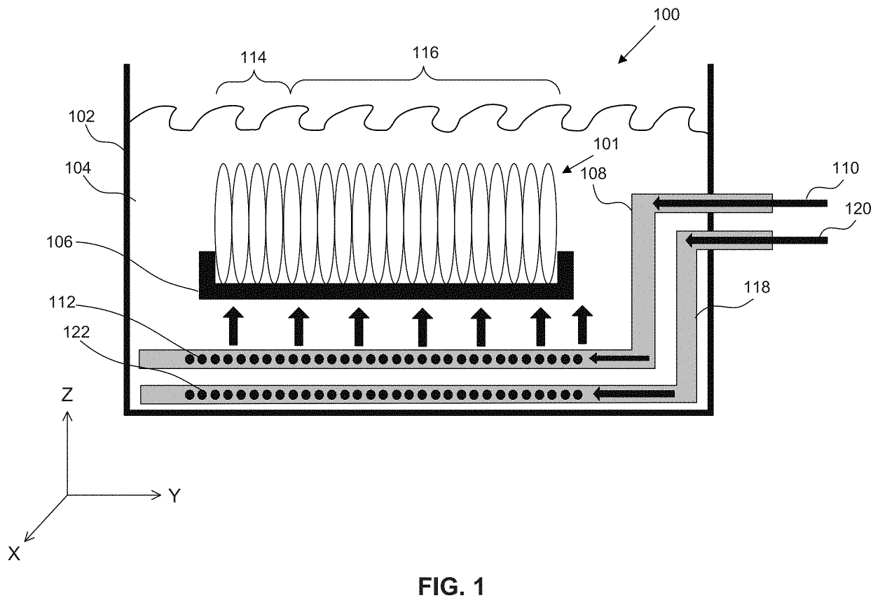

FIG. 1 illustrates an example etching bath basin 100 (hereafter simply “bath”), according to an embodiment. Etching apparatus 100 includes a bath 102 that contains a first liquid 104. During operation, one or more wafers 101 are submerged into first liquid 104. First liquid 104 may be any liquid that does not react adversely with any of one or more wafers 101, or any materials disposed on one or more wafers 101. For example, first liquid 104 can be de-ionized water. In some embodiments, one or more wafers 101 are loaded first into a boat structure 106, and boat structure 106 is then lowered into first liquid 104.

Bath 102 can be dimensioned to receive a large number of wafers at the same time for performing an etching operation. For example, bath 102 can be large enough to receive up to 20 or 25 4-inch or 6-inch wafers at a time, where the wafers are separated from each other by a short distance (e.g., less than 10 mm.)

Etching apparatus 100 includes a liquid supply pipe 108 that runs along a bottom portion of bath 102, and underneath one or more wafers 101. Liquid supply pipe 108 is designed to deliver a second liquid 110 that flows through liquid supply pipe 108 and into bath 102. Second liquid 110 flows through a first plurality of openings 112 in liquid supply pipe 108 to be delivered into first liquid 104. First plurality of openings 112 can each have a diameter between about 0.10 mm and 0.20 mm.

Second liquid 110 can be any chemical used to etch or remove material on one or more wafers 101. For example, second liquid 110 can include phosphoric acid, which is used to etch any exposed silicon nitride on one or more wafers 101. Another example of second liquid 110 can include hydrofluoric acid for etching exposed silicon oxide. By flowing second liquid 110 through openings 112 beneath one or more wafers 101, second liquid 110 circulates around one or more wafers 101. The etch rate at each of one or more wafers 101 depends on how well second liquid 110 can circulate. Due to the flow direction through liquid supply pipe 108, the flow rate of second liquid 110 can be slower coming out of openings 112 that are further away from the inlet. The result is that the circulation of second liquid 110 around a first portion of wafers 114 is poorer than the circulation of second liquid 110 around a second portion of wafers 116. This poorer circulation around first portion of wafers 114 results in slower etch rates for first portion of wafers 114 compared to second portion of wafers 116. First portion of wafers 114 can include as many as 5 wafers.

According to an embodiment, etching apparatus 100 also includes a gas supply pipe 118 that runs along a bottom portion of bath 102 beneath one or more wafers 101. Gas supply pipe 118 can run substantially parallel to liquid supply pipe 108. Although gas supply pipe 118 is illustrated in FIG. 1 as being separated from liquid supply pipe 108 in the Z-direction, this is for illustrative purposes only and is not intended to be limiting. Gas supply pipe 118 can be separated from liquid supply pipe 108 in any direction.

Gas supply pipe 118 can be designed to deliver a gas 120 into bath 102 via a second plurality of openings 122. Gas 120 bubbles up through openings 122 within first liquid 104. According to some embodiments, gas 120 is any chemically inert gas. For example, gas 120 can be nitrogen or argon.

Second plurality of openings 122 can have similar dimensions and spacing along gas supply pipe 118 as first plurality of openings 112 along liquid supply pipe 108. For example, each opening of second plurality of openings 122 can be aligned with a corresponding opening of first plurality of openings 112 in a direction that is perpendicular to the length (e.g., in the Y-direction) of each of gas supply pipe and liquid supply pipe running along the bottom of bath 102. Each of liquid supply pipe 108 and gas supply pipe 118 can have the same cross-section dimensions as they run along the bottom portion of bath 102.

According to an embodiment, during an etching process, second liquid 110 and gas 120 are introduced into first liquid 104 simultaneously. The presence of the bubbles produced by gas 120 in first liquid 104 agitates the region around each of one or more wafers 101, and thus allows for more efficient circulation of second liquid 110 around each of one or more wafers 101. The result is a more uniform etch rate among each of one or more wafers 101, regardless of each wafer's position in bath 102.

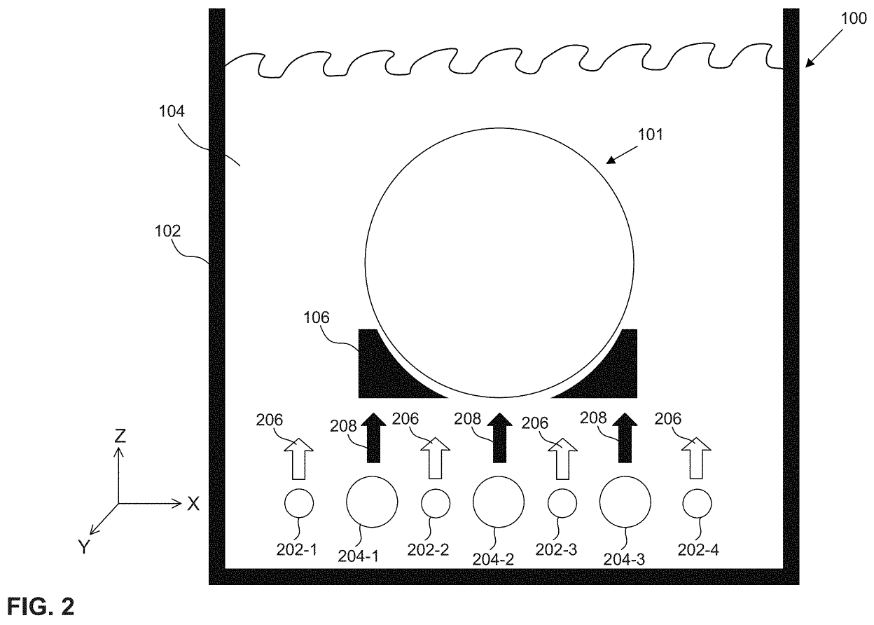

FIG. 2 illustrates another view of etching apparatus 100 taken across the Z-X plane, according to an embodiment. More than one gas supply pipe 202-1 to 202-4 is provided beneath one or more wafers 101, and more than one liquid supply pipe 204-1 to 204-3 is provided beneath one or more wafers 101, according to some embodiments. Any number of gas supply pipes 202 and liquid supply pipes 204 can be used. Each gas supply pipe 202-1 to 202-4 can be arranged to run parallel to each other and/or parallel to each of liquid supply pipe 204-1 to 204-3.

As illustrated in FIG. 2, each gas supply pipe 202-1 to 202-4 and liquid supply pipe 204-1 to 204-3 can be arranged next to each other along the X-direction, although this is not required. Arrows 206 are used to indicate the flow of gas into first liquid 104 from each of gas supply pipe 202-1 to 202-4 while arrows 208 are used to indicate the flow of etchant liquid into first liquid 104 from each of liquid supply pipe 204-1 to 204-3.

According to some embodiments, each of gas supply pipe 202-1 to 202-4 is fed by a same inlet pipe that braches into each of gas supply pipe 202-1 to 202-4. Similarly, each of liquid supply pipe 204-1 to 204-3 can be fed by a same inlet pipe that braches into each of liquid supply pipe 204-1 to 204-3. Valves can be used on any one of gas supply pipe 202-1 to 202-4 or liquid supply pipe 204-1 to 204-3 to control the flow rate of the gas/liquid through the pipe.

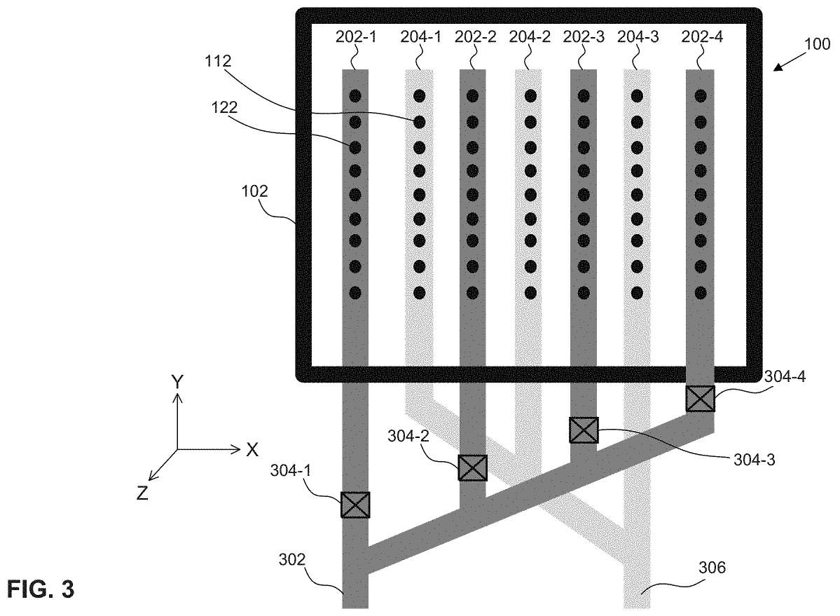

FIG. 3 illustrates another view of etching apparatus 100 taken across the X-Y plane, according to an embodiment. Each of gas supply pipe 202-1 to 202-4 and liquid supply pipe 204-1 to 204-3 are illustrated within bath 102, running parallel to one another. The one or more wafers are not illustrated for clarity, but would be located above the gas supply pipes 202-1 to 202-4 and liquid supply pipes 204-1 to 204-3 in the Z-direction. First plurality of openings 112 are arranged along a length of each of liquid supply pipe 204-1 to 204-3 and second plurality of openings 122 are arranged along a length of each of gas supply pipe 202-1 to 202-4, according to some embodiments.

Each liquid supply pipe 204-1 to 204-3 can combine into a single liquid inlet pipe 306, according to an embodiment. Liquid supply pipe 204-1 to 204-3 can combine together outside of bath 102, although this is not required. Each of liquid supply pipe 204-1 to 204-3 can include valves (not shown) to control the flow rate of liquid within each liquid supply pipe 204-1 to 204-3 separately. It should be understood that liquid supply pipe 204-1 to 204-3 can also each be a separate pipe with a separate liquid inlet, thus allowing for different liquids to flow simultaneously through each of liquid supply pipe 204-1 to 204-3.

Each gas supply pipe 202-1 to 202-4 can combine into a single gas inlet pipe 302, according to an embodiment. Gas supply pipe 202-1 to 202-4 can combine together outside of bath 102, although this is not required. Each of gas supply pipe 202-1 to 202-4 can include valves 304-1 to 304-4, respectively, to control the flow rate of gas within each gas supply pipe 202-1 to 202-4 separately. This allows for fine-tuned control of how much gas is used within bath 102 and where the gas is used within bath 102. For example, valves 304-1 to 304-4 can control the flow of gas such that more gas is delivered to a portion of bath 102 where wafers were found to have poor liquid circulation. The increased number of gas bubbles at the location can help improve the liquid circulation there. It should be understood that gas supply pipe 202-1 to 202-4 can also each be a separate pipe with a separate gas inlet, thus allowing for different gases to flow simultaneously through each of gas supply pipe 202-1 to 202-4.

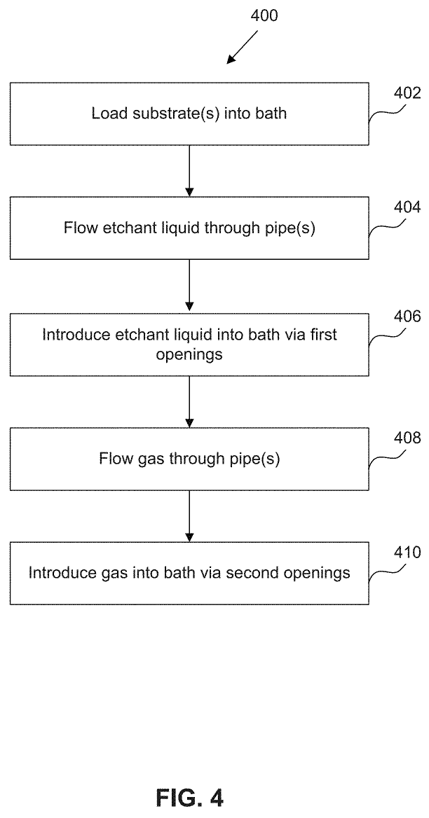

FIG. 4 is a flowchart of an exemplary method 400 for chemical etching one or more substrates, according to some embodiments. The operations of method 400 can be performed using etching apparatus 100 described with reference to FIGS. 1-3. It should be understood that the operations shown in method 400 are not exhaustive and that other operations can be performed as well before, after, or between any of the illustrated operations. In various embodiments of the present disclosure, the operations of method 400 can be performed in a different order and/or vary.

In operation 402, one or more substrates are loaded into a bath. The bath can include de-ionized water. The one or more substrates are submerged entirely into the liquid held within the bath, according to an embodiment. The one or more substrates can be first loaded into a boat structure and subsequently submerged into the bath. The boat structure can be designed to hold up to 25 or up to 50 substrates.

In operation 404, an etchant liquid is flown through one or more liquid supply pipes. The etchant liquid may differ depending on what material is desired to be etched or removed from the one or more substrates. Example etchant liquids include phosphoric acid or hydrofluoric acid. The one or more liquid supply pipes can run along a lower portion of the bath. In some embodiments, the liquid supply pipes run parallel to each other.

In operation 406, the etchant liquid is introduced into the bath via first openings along the one or more liquid supply pipes. The one or more liquid supply pipes are arranged such that the etchant liquid is introduced into the bath beneath the one or more wafers, according to an embodiment. The first openings can be arranged along a length of each of the one or more liquid supply pipes as they run along a bottom portion of the bath. The etchant liquid may mix with whatever liquid is contained within the bath, or may be immiscible with whatever liquid is contained within the bath.

In operation 408, gas is flown through one or more gas supply pipes. The gas can be any inert gas, such as argon or nitrogen. The gas can be flown through the one or more gas supply pipes at the same time that etchant liquid is flown through the one or more liquid supply pipes. The one or more gas supply pipes can run along a lower portion of the bath. In some embodiments, the gas supply pipes run parallel to each other, and parallel to each of the one or more liquid supply pipes.

Each of the one or more gas supply pipes can include a valve to control the gas flow rate in the corresponding gas supply pipe. The flow rate in each of the one or more gas supply pipes can be adjusted using the valves to control how much gas is delivered, and where the gas is delivered.

In operation 410, the gas is introduced into the bath via second openings along the one or more gas supply pipes. The one or more gas supply pipes are arranged such that the gas is introduced into the bath beneath the one or more wafers, according to an embodiment. The second openings can be arranged along a length of each of the one or more gas supply pipes as they run along a bottom portion of the bath. In some embodiments, the second openings are arranged to align with the first openings in a direction perpendicular to the length of each of the one or more gas supply pipes.

According to some embodiments, the gas is introduced into the bath via the second openings at the same time that the etchant liquid is introduced into the bath via the first openings. The gas bubbles formed from the gas being forced up into the bath agitate the liquid within the bath and can improve liquid circulation around the one or more substrates with the bath. The improved circulation allows for the etchant liquid to more easily access all surfaces of the one or more substrates, yielding uniform etch rates among the one or more substrates.

The present disclosure describes various embodiments of a chemical etching apparatus and methods of using said apparatus. In some embodiments, an apparatus used for chemical etching of one or more substrates includes a bath designed to hold a first liquid and to hold the one or more substrates submerged within the first liquid. A liquid supply pipe runs along a bottom portion of the bath. The liquid supply pipe has a first plurality of openings along a length of the liquid supply pipe along the bottom portion of the bath. A gas supply pipe runs along the bottom portion of the bath. The gas supply pipe has a second plurality of openings along a length of the gas supply pipe along the bottom portion of the bath. The liquid supply pipe introduces a second liquid into the first liquid via the first plurality of openings and the gas supply pipe introduces a gas into the first liquid via the second plurality of openings.

In some embodiments, the method for chemically etching one or more substrates includes loading one or more substrates into a bath designed to hold a first liquid. The method also includes flowing a second liquid through a liquid supply pipe running along a bottom portion of the bath, and introducing the second liquid into the first liquid via a first plurality of openings along a length of the liquid supply pipe that runs along the bottom portion of the bath. The method includes flowing a gas through a gas supply pipe running along the bottom portion of the bath, and introducing the gas into the first liquid via a second plurality of openings along a length of the gas supply pipe that runs along the bottom portion of the bath.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Embodiments of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all exemplary embodiments of the present disclosure as contemplated by the inventor(s), and thus, are not intended to limit the present disclosure and the appended claims in any way.

The breadth and scope of the present disclosure should not be limited by any of the above-described exemplary embodiments, but should be defined only in accordance with the following claims and their equivalents.

What is claimed is:

1. An apparatus used for chemical etching, comprising:
a bath configured to hold a first liquid;
a liquid supply pipe running along a bottom portion of the bath, the liquid supply pipe having a first plurality of openings along a length of the liquid supply pipe along the bottom portion of the bath; and
a gas supply pipe running along the bottom portion of the bath, the gas supply pipe having a second plurality of openings along a length of the gas supply pipe along the bottom portion of the bath,
wherein the liquid supply pipe is configured to introduce a second liquid into the first liquid via the first plurality of openings and the gas supply pipe is configured to introduce a gas into the first liquid via the second plurality of openings.

2. The apparatus of claim 1, wherein the bath is configured to support a structure configured to hold one or more substrates.

3. The apparatus of claim 1, wherein the gas comprises nitrogen.

4. The apparatus of claim 1, wherein each of the first plurality of openings and second plurality of openings has a diameter between 0.10 mm and 0.20 mm.

5. The apparatus of claim 1, wherein the liquid supply pipe and the gas supply pipe run parallel to each other along the bottom portion of the bath.

6. The apparatus of claim 5, wherein each of the first plurality of openings is aligned with a corresponding opening of the second plurality of openings in a direction perpendicular to the length of each of the gas supply pipe and the liquid supply pipe.

7. The apparatus of claim 1, further comprising a plurality of liquid supply pipes, each running along the bottom portion of the bath and parallel to each other.

8. The apparatus of claim 1, further comprising a plurality of gas supply pipes each running along the bottom portion of the bath and parallel to each other.

9. The apparatus of claim 8, wherein the plurality of gas supply pipes combine into a single inlet gas pipe outside of the bath.

10. The apparatus of claim 8, further comprising a valve on each of the plurality of gas supply pipes, and configured to independently control a flow rate of gas within each of the plurality of gas supply pipes.

11. A chemical etching method, comprising:
loading a first liquid into a bath;
flowing a second liquid through a liquid supply pipe running along a bottom portion of the bath;
introducing the second liquid into the first liquid via a first plurality of openings along a length of the liquid supply pipe that runs along the bottom portion of the bath;
flowing a gas through a gas supply pipe running along the bottom portion of the bath; and
introducing the gas into the first liquid via a second plurality of openings along a length of the gas supply pipe that runs along the bottom portion of the bath.

12. The method of claim 11, further comprising loading one or more substrates into a structure, and submerging the structure into the bath holding the first liquid.

13. The method of claim 12, further comprising etching a material on the one or more substrates using at least the second liquid.

14. The method of claim 11, wherein flowing the second liquid and flowing the gas occurs simultaneously.

15. The method of claim 11, wherein flowing the second liquid comprises flowing the second liquid through a plurality of liquid supply pipes along the bottom portion of the bath.

16. The method of claim 11, wherein flowing the gas comprises flowing the gas through a plurality of gas supply pipes along the bottom portion of the bath.

17. The method of claim 16, further comprising adjusting a flow rate of the gas within each of the plurality of gas supply pipes using valves coupled to each of the plurality of gas supply pipes.

18. The method of claim 11, further comprising agitating the first liquid and the second liquid using the gas introduced into the first liquid via the second plurality of openings.

19. The method of claim 11, wherein flowing the gas comprises flowing nitrogen.

20. The method of claim 11, wherein introducing the second liquid into the first liquid and introducing the gas into the first liquid occurs simultaneously.
